(19) United States
(12) Patent Application Publication
(10) Pub. No.: US 2024/0006547 A1
(43) Pub. Date: Jan. 4, 2024

(54) LIGHT CONTROLLING PHOTOVOLTAIC MODULE AND METHOD

(71) Applicant: KING ABDULLAH UNIVERSITY OF SCIENCE AND TECHNOLOGY, Thuwal (SA)

(72) Inventors: Thomas Gerald ALLEN, Thuwal (SA); Emmanuel P. VAN KERSCHAVER, Thuwal (SA); Michele DE BASTIANI, Thuwal (SA); Ahmed Hesham BALAWI, Thuwal (SA); Michael Filipe SALVADOR, Thuwal (SA)

(21) Appl. No.: 18/038,566

(22) PCT Filed: Dec. 1, 2021
(86) PCT No.: PCT/IB2021/061186

§ 371 Date: May 24, 2023

Related U.S. Application Data
(60) Provisional application No. 63/122,154, filed on Dec. 7, 2020.

(51) Int. Cl. H01L 31/054; H02S 20/23; H01L 31/048; H01L 31/18

(52) U.S. Cl. CPC H01L 31/054; H02S 20/23; H01L 31/0488; H01L 31/0547; H01L 31/18

(57) ABSTRACT

A photovoltaic module for transforming an incident light into electrical energy includes plural solar cell configured to transform the incident light into the electrical energy; a first sheet that is transparent to the incident light; and a second sheet that is transparent to the incident light. The plural solar cell are sandwiched between the first sheet and the second sheet. At least one of the first and second sheets has a high transparency regarding the incident light and also a high scattering of the incident light.

### CROSS-REFERENCE TO RELATED APPLICATIONS

This application claims priority to U.S. Provisional Patent Application No. 63/122,154, filed on Dec. 7, 2020, entitled “LIGHT DIFFUSING PHOTOVOLTAIC SCREEN FOR UNIFORM LIGHT DISTRIBUTION,” the disclosure of which is incorporated herein by reference in its entirety.

### BACKGROUND

### Technical Field

Embodiments of the subject matter disclosed herein generally relate to a photovoltaic device, and more particularly, to a semi-transparent photovoltaic device that implements uniform light distribution behind the photovoltaic device, in addition to light conversion into electrical energy.

### Discussion of the Background

Conventional photovoltaic devices 100, as illustrated in FIG. 1, include plural silicon based solar cells 110 electrically connected to each other and supported by a common substrate 120. A protection layer (not shown) may be formed over the solar cells 110 to protect them from external factors as humidity, scratching, etc. while the protection layer is made to be as transparent as possible to not impede the amount of solar energy that is received by the solar cells 110. The substrate 120 is typically made of an opaque material, that does not allow solar energy to pass through it. These photovoltaic devices are currently being installed on the roofs of various buildings or as standalone units in solar energy farms, for capturing the solar energy and transforming it into electrical energy. For this reason, each solar cell 110 is typically formed of semiconductor materials that have the property to capture the solar energy and transform it into electrical energy. Such semiconductor materials are known to be opaque to the solar radiation, thus not allowing the light to pass through.

However, there is currently a movement about not only capturing the solar energy with these traditional photovoltaic cells and transforming it into electrical energy, but also allowing part of the incident light to pass through the photovoltaic device to illuminate a habitat that exists behind the cells. In this regard, FIG. 2 shows a structure 200, for example, a chamber, a greenhouse, a room in an apartment, a space in a factory, a hall in a hospital, etc., which is configured to have a transparent roof 210 such that light 220 is entering inside the structure 200. The roof 210 is configured to support one or more photovoltaic devices 100 so that part of the solar energy 220 is collected and transformed into electrical energy for consumption inside the structure, for example, by an appliance 230.

Due to the fact that the traditional photovoltaic device 100 is opaque to the light 220, various patterns of shades 240 are formed inside the structure 200. These patterns are not attractive for the inhabitants of the structure 200, and also may discourage visitors of these structures to return, which is undesirable especially if the structure is associated with a business that needs human traffic inside.

To address this problem, more recent photovoltaic devices have been designed to be semi-transparent photovoltaic panels that house the silicon solar cells 100. Such semi-transparent solar panels can be installed, for instance, in the building façade as part of a window structure. Semi-transparency as used here refers to photovoltaic devices with an optical transmission of about 10% to about 60% and excludes the common photovoltaic modules (solar panels) 100 as found on rooftops and in solar farms as those modules are not designed to transmit the incident light.

The semi-transparent solar devices need to have the front and back layers made of a transparent material. Because highly transparent materials are employed in the front and back of such solar modules, typically glass, the embedded opaque solar cells 100 still cast a shadow pattern consistent with the footprint of the solar cells in the solar module. Thus, the light distribution behind the solar devices inside the structure 100 is still inhomogeneous and the shadow pattern 240 still changes along the day, depending on the location of the sun. These effects of the changing patterns throughout the day inside the structure still have notable implications on the aesthetics of the interior design, the optical perception and comfort of the users of the building, the energy balance and interior temperature of the building and especially for light sensitive environments.

In this regard, the integration of the solar devices in the rooftop of the greenhouses is an example of such light sensitive environment. The solar cells will cast a shadow pattern onto the crops, which may introduce spatial variations in the growth of the produce. This could reduce the production and thus the revenue of a greenhouse farmer.

Thus, there is a need for a new solar module that is capable not only of capturing the solar energy and transforming it into electrical energy, but also for allowing part of the solar light to pass through the solar module and to be distributed inside the structure that holds the solar module with minimum shade patterns, i.e., to achieve a uniform light intensity distribution behind the solar module.

### BRIEF SUMMARY OF THE INVENTION

According to an embodiment, there is a photovoltaic module for transforming an incident light into electrical energy. The photovoltaic module includes plural solar cell configured to transform the incident light into the electrical energy, a first sheet that is transparent to the incident light, and a second sheet that is transparent to the incident light. The plural solar cells are sandwiched between the first sheet and the second sheet. At least one of the first and second sheets has a high transparency regarding the incident light and also a high scattering of the incident light.

According to another embodiment, there is a photovoltaic module for transforming an incident light into electrical energy, and the photovoltaic module includes plural solar cells configured to transform the incident light into the electrical energy, a first sheet that is transparent to the incident light, a second sheet that is transparent to the incident light, and an encapsulating material distributed between the first and second sheets to hold the first and second sheets together. The plural solar cells and the encapsulating material are sandwiched between the first sheet and the second sheet. At least one of the first and second sheets has a high transparency regarding the incident light and also a high scattering of the incident light.

According to yet another embodiment, there is a method for generating substantially uniform light intensity behind a solar module. The method includes selecting a first sheet having a high light transmittance, providing an encapsulating material over the first sheet, embedding plural solar cells into the encapsulating material, selecting a second sheet having a high light transmittance and a high light scattering, and placing the second sheet over the embedded plural solar cells and the encapsulating material so that the first sheet, the encapsulating material, the plural cells and the second sheet form the solar module. Incident light on the first sheet scatters after passing the second sheet so that the passing light does not produce minima and maxima of light intensities.

The above embodiments may be combined with one or more of the following features for achieving superior light management and power conversion efficiency: A) the first sheet is coated with an anti-reflection coating to minimize the reflection of the incident light and maximize the light capturing for increasing the solar cell generated current, B) a layer for matching the refractive index is embedded between the first sheet and the encapsulant with the aim of trapping the light in the module for increasing the solar cell generated current, and C) a back reflector is applied between the encapsulating material and the second sheet or in the back of the second sheet. The back reflector is either uniformly applied or striped to minimize the shading pattern cast below the modules while increasing the solar cell generated current.

### BRIEF DESCRIPTION OF THE DRAWINGS

For a more complete understanding of the present invention, reference is now made to the following descriptions taken in conjunction with the accompanying drawings, in which:

FIG. 1 is a schematic diagram of a solar module having plural solar cells that transform solar energy into electrical energy;

FIG. 2 illustrates a structure that has one or more solar modules on its roof;

FIG. 3 illustrates a cross-section through a solar module;

FIGS. 4A and 4B illustrate a novel solar module that achieves almost uniform light intensity after the light passes through the solar module;

FIG. 5 compares the photosynthetic photon flux density versus time for a conventional shade screen and for the novel solar module noted above;

FIGS. 6 to 8 illustrate various embodiments of the novel solar module;

FIG. 9 illustrates the amount of transmitted light and the amount of scattered light by various solar modules;

FIG. 10A shows a surface feature between opaque solar cells that scatters the light, FIG. 10B shows an internal nanofeature associated with the solar module that also scatters the light, and FIGS. 10C and 10D show the addition of a highly reflective sheet to channel the light between the cells back to the cells;

FIGS. 11A to 11C illustrate various novel solar modules having a changing light scattering feature; and

FIG. 12 is a flow chart of a method for making the novel solar module.

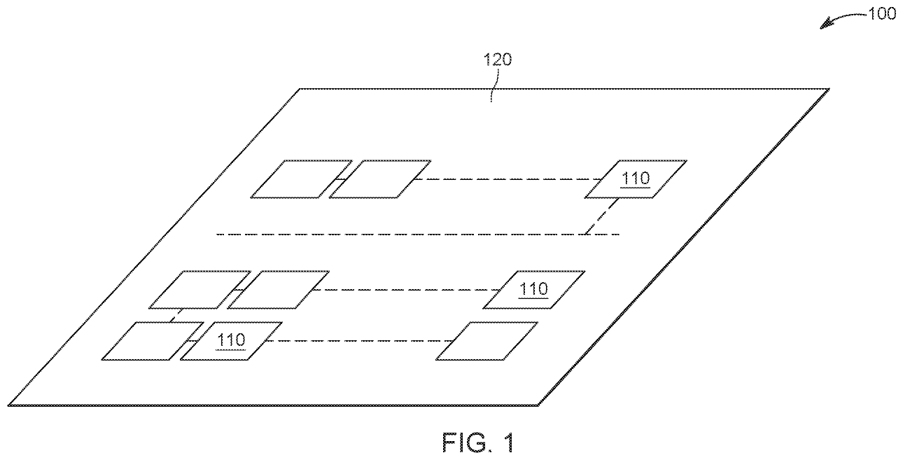

### DETAILED DESCRIPTION OF THE INVENTION

The following description of the embodiments refers to the accompanying drawings. The same reference numbers in different drawings identify the same or similar elements. The following detailed description does not limit the invention. Instead, the scope of the invention is defined by the appended claims. The following embodiments are discussed, for simplicity, with regard to a solar module that provides a more uniform light intensity distribution behind the solar module when the solar module is provided in a greenhouse. However, the embodiments to be discussed next are not limited to a solar module being provided in a greenhouse, but they are applicable to any structure to which or in which the solar module is used.

Reference throughout the specification to “one embodiment” or “an embodiment” means that a particular feature, structure or characteristic described in connection with an embodiment is included in at least one embodiment of the subject matter disclosed. Thus, the appearance of the phrases “in one embodiment” or “in an embodiment” in various places throughout the specification is not necessarily referring to the same embodiment. Further, the particular features, structures or characteristics may be combined in any suitable manner in one or more embodiments.

According to an embodiment, a solar module is made to be lightweight (e.g., up to 1-2 kg/m²), semitransparent (total light transmission of 10% to 70%), and to be including a combination of highly transparent front and back sheets that allow controllable light transmission while simultaneously scattering the light behind the module, i.e., with a diffuse (scattered) light transmission larger than 10% and up to 60% across a wavelength range of 300-1200 nm, after passing through the solar module. In practice this means that the embedded solar cells, which are arranged in a given pattern, although being opaque, will cast a uniform shadow behind the solar module while blocking the sunlight. This solar module eliminates the problems mentioned above in the Background section. In particular, when considering greenhouse farming, a uniform light distribution will ensure uniform crop growth and yield across the area behind the solar module.

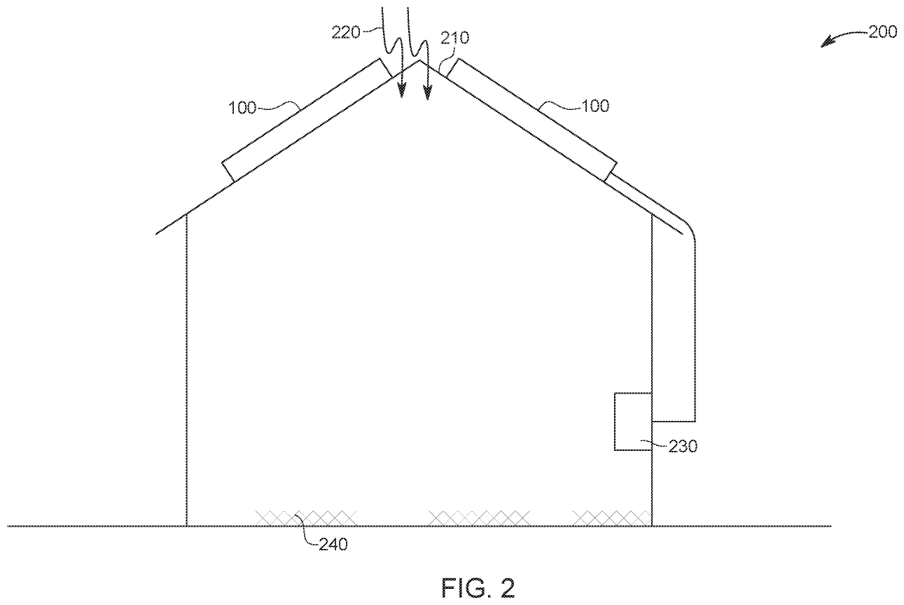

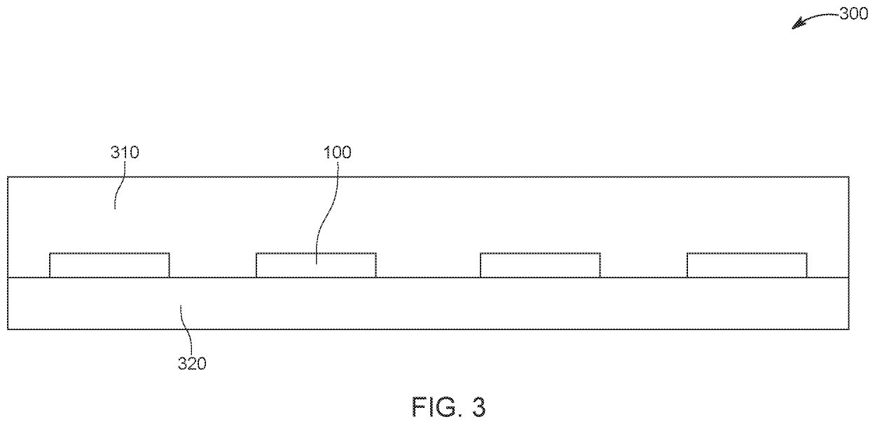

Conventionally, a semi-transparent photovoltaic module 300 with optical transmission larger than 10% is manufactured, as shown in FIG. 3, to have a combination of (a) a glass sheet 310 in the front and (b) a glass sheet 320 in the back or, alternatively, the glass sheet in the front and a transparent plastic back sheet in the back. In some rare cases, with regard to thin-film photovoltaics, plastic barriers are used in the front and in the back of the photovoltaic devices. These materials in the front and back of the solar cells are selected to maximize the light transmission and minimize the penetration of harmful contaminants such as moisture and oxygen from the environment. In addition, the front glass is optimized for minimum light reflection and maximum light transmission. The embedded solar cells cast a shadow behind the solar module, as previously discussed with regard to FIG. 2, which is usually neither addressed nor controlled. This is so because the conventional solar modules are not designed for achieving uniform light distribution behind the solar module (after light penetration through the rear side of the module), thus leaving the problem of shadow casting unsolved.

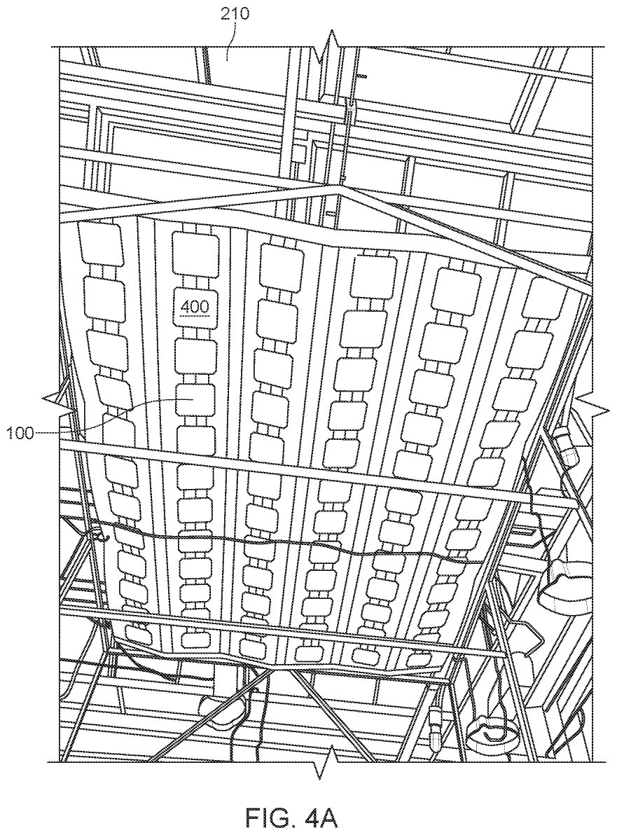

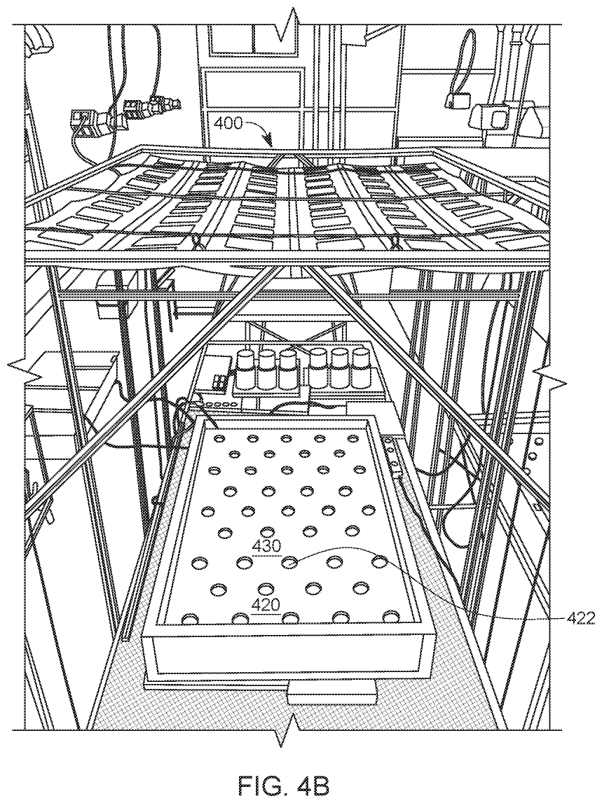

However, the new photovoltaic module 400 illustrated in FIGS. 4A and 4B is configured to scatter the passing light almost uniformly so that no shade pattern is formed behind the module. FIG. 4A shows the photovoltaic module 400 located inside a greenhouse. The roof 210 of the greenhouse can be seen above the module 400. A plant bed 420 is shown in FIG. 4B being located inside the greenhouse, and various plants 422 are planted in this plant bed. The light pattern 430 projected on the plant bed because of the module 400 is noted to be very uniform, without strong high and low light intensities. In FIG. 4A, as the light is scattered substantially uniformly by the materials making up the module 400, various objects behind the screen inside the greenhouse cannot be distinguished although the screen features a transparency of about 80% between the cells and the image was taken against the sun light.

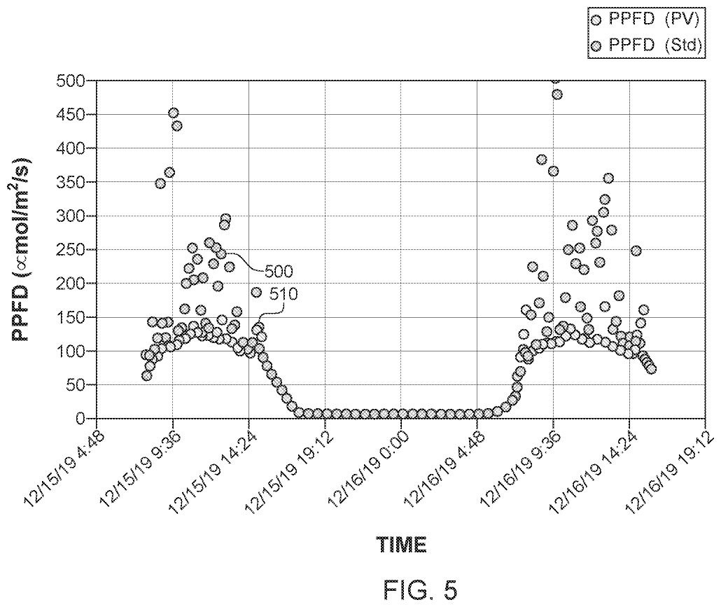

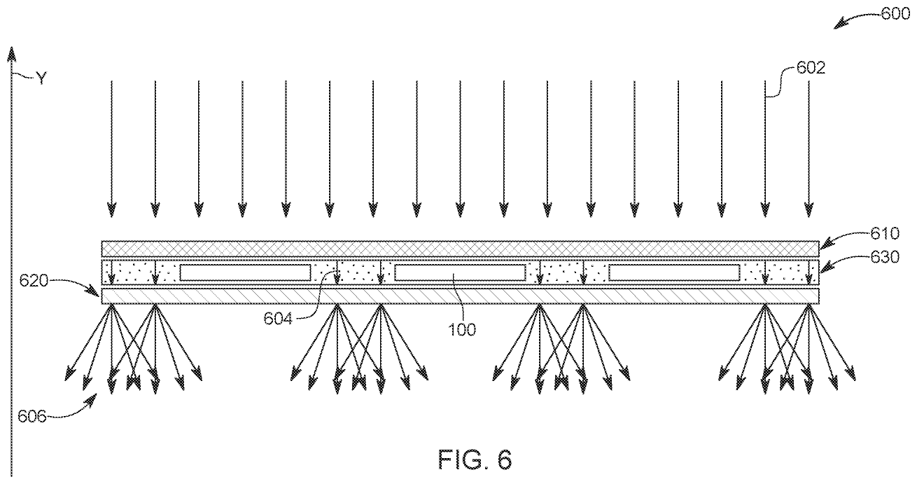

The inventors have compared the light observed behind a photovoltaic device, due to the scattering introduced by the solar module 400, and due to the transmission through a conventional shade screen, and measured this light when arriving at a light sensor placed behind the standard screen and the scattering solar module 400 as a function of daytime. FIG. 5 plots these measurements with the photosynthetic photon flux density (PPFD) on the Y axis and the time on the X axis. PPFD is the amount of photoactive radiation that arrives at the plant in the greenhouse, after passing through the photovoltaic module or the shade screen. While strong variations 500 in the light intensity are recorded under the standard shade cloth, a phenomenon that could be compared with a partly cloudy day with mixed shading, the light intensity 510 generated by the solar panel 400 proves to be more effective in scattering and diffusing the light, as demonstrated by the much more uniform curve recorded in FIG. 5, which more closely resembles a plateau.

To achieve the almost uniform distribution of the light intensity (see FIG. 5) behind a photovoltaic device that has opaque elements integrated therein, the novel photovoltaic module 400 uses one or more materials that not only transmit the light, but also scatter it. Provided that there is sufficient space between the opaque elements (i.e., solar cells 100) along a length of the solar module 400, the incoming light will be transmitted and scattered in between the opaque elements. With increasing the distance from the solar module 400 to an observation point behind the solar module, the scattered light perceived at the observation point will again homogenize into a uniform, albeit reduced, light intensity, which dramatically reduces the pattern of shadows.

More specifically, as shown in FIG. 6, a first implementation 600 of the photovoltaic module 400 includes the opaque solar cells 100 sandwiched between a first sheet 610 (front sheet) and a second sheet 620 (back sheet). The first sheet 610 is also called the front sheet and the second sheet 620 is also called the back sheet. The terms “front” and “back” are defined relative to the source of light, i.e., the sheet on which the incoming light 602 impinges first is the front sheet and the sheet on which the incoming light impinges last is the back sheet. In other words, the light enters the module 600 through the front sheet and exits through the back sheet. The solar cell 100 can be any of the existing photovoltaic cell. The number of solar cells 100 present into a given module 600 can vary from 2 to any larger integer.

To utilize the maximum incident light to the novel solar panel 400, an anti-reflection coating can be added to the front sheet in order to minimize the light reflection from the light source facing side. The additional captured light can then be utilized to generate extra solar cell current and/or light transmission to the observation point behind the solar panel. Another method to utilize the incident light for maximum solar cell current generation is to maximize the light trapping inside the solar panel by matching the refractive index of the different layers of the front sheet and the back sheet to increase the path length of light inside the solar panel 400.

The solar cells 100 may be placed in an encapsulating material 630. The encapsulating material 630 may be a material that promotes the lamination of the solar cells 100 between the first and second sheets 610 and 620, i.e., may include a material that permanently attaches to the first and second sheets 610 and 620. In one embodiment, the encapsulating material 630 is provided to fully encapsulate the solar cells 100. In this embodiment or another embodiment, the encapsulating material 630 fully extends between the first and second sheets 610 and 620, so that there is no direct contact between the first and second sheets. In one embodiment, the encapsulating material may be any resin, ionoplastic or even an organic material (e.g., polymer) like ethylene vinyl acetate (EVA), polyvinyl butyral (PVB) or polyolefin elastomer (POE). The encapsulating material and the first and second sheets may be made of flexible materials so that a space between the solar cells 100 can be bended up to 180 degrees and thus it can be rolled. In one embodiment, the first sheet 610 is made of a first material and the second sheet is made of a second material, different from the first material. However, as discussed later, the first and second layers may be made of the same material. In the embodiment illustrated in FIG. 6, the first layer 610 is formed of glass or plastic film or any other polymer that allows the light to pass through without changing its direction, i.e., low scattering.

The selection of the material for the first and second sheets 610 and 620 is made based on two characteristics of the material: (1) the light transmittance, which characterizes how much of the incident light is allowed to pass through the material, and (2) the light scattering, which characterizes how much of the incident light is diffused, i.e., it is deviated from its original incident direction. In the following, a highly transmissive material is considered any material that allows at least 85% of the incident light to pass through the material, for a given thickness of the material. Any material that transmits light in the range of 85 to 30% is considered to be just a “transmissive material” and a material that transmits less than 30% of the incident light is considered to be poorly transmissive. Also, in the following, a highly scattering material is considered to be any material that randomly changes the direction of the incoming light rays of more than 40% or even more than 50% of the incoming light, i.e., a diffusion of 40% or 50%. A low scattering material is considered to be any material that has a diffusion of less than 5% of the incoming light. A scattering material is considered to be a material that changes the direction of the incident light for about 5 to 50% of the incident light rays.

For the embodiment illustrated in FIG. 6, the first sheet 610 is selected to be highly transmissive, i.e., the light transmittance is 85% or higher, and the material of the first sheet 610 is also selected to be low scattering, i.e., a light scattering of less than 5%. The encapsulation material 630 is selected to have the same light properties as the first layer 610, i.e., high transmission and low scattering. With this selection of the layers making up the module 600, most of the incident light 602 passes almost unchanged through the first layer 610 and the encapsulating material 630, as illustrated by arrows 604. However, when this light 604 reaches the second layer 620, which is selected to be highly transmissive but also highly scattering (i.e., scattering more than 50% of the incident light 604), the incident light 604 becomes highly scattered light 606, thus, changing its direction from the original direction Y of the incident light 602. In this way, the scattered light 606 that is present behind the module 600 homogenize into a uniform light, but with a reduced intensity due to the light absorption of each layer and also because the solar cells 100 block part of the incoming light. However, the resultant light 606 does not form patterns as most of the light rays are spread in various directions and thus, no matter how the original source of light moves relative to the solar module 600, the almost uniform spreading of the resultant light 606 remains, which gives to the viewer behind the solar module the impression of a uniform distribution light intensity.

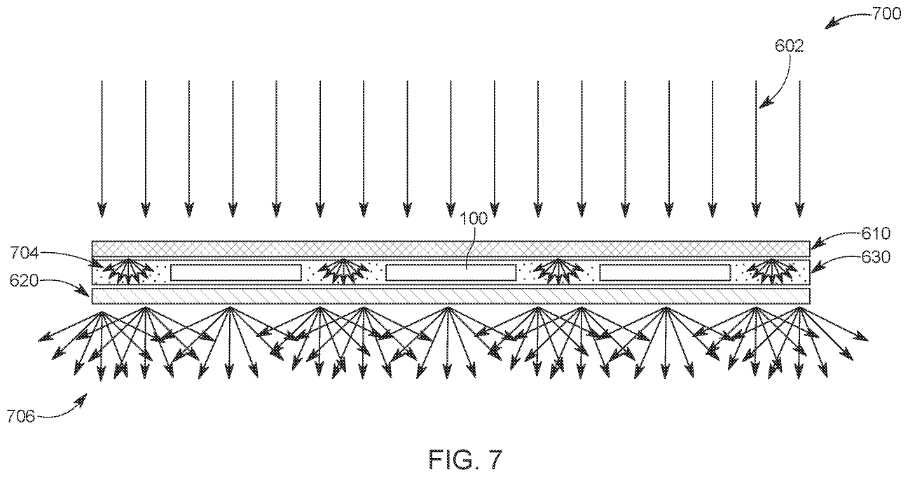

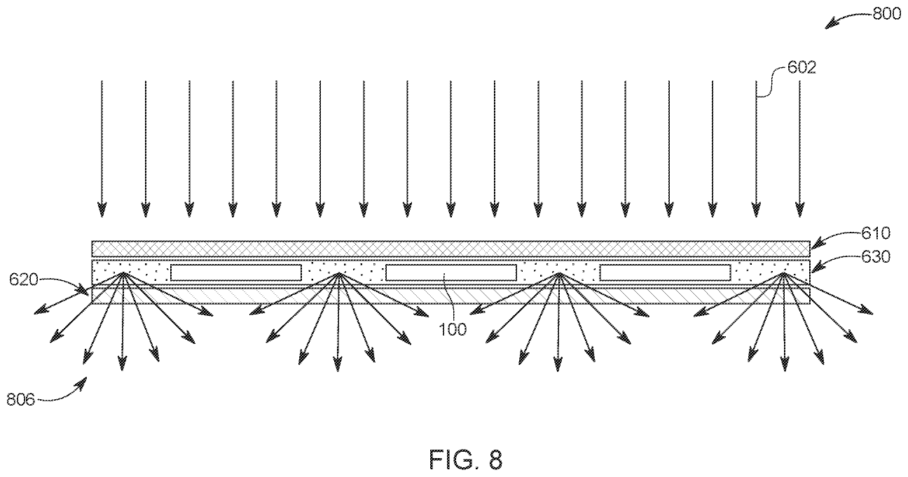

In another embodiment, as illustrated in FIG. 7, not only the second layer 620 is selected to be highly transmissive and highly scattering, but also the first layer 610 is selected to be highly transmissive and highly scattering. This means that the light 704 entering the encapsulating material 630 is already highly scattered and thus, the light 706 that passes through the second layer 620 is more scattered from the incident direction Y than the light 606 in FIG. 6. This means that this type of module 700 would produce a more uniform light intensity after the incident light passes through the entire module.

In yet another embodiment illustrated in FIG. 8, the implementation 800 of the solar module 400 has the encapsulating material 630 selected to have a high transmittance and a high scattering (i.e., light diffusion of more than 50% of the incoming light) property so that the light 806 emerging from the solar module is also scattered while propagating through the encapsulating material. For this embodiment, either one of the first and second layers 610 and 620 can be highly transmissive and highly scattering, or both the first and second layers 610 and 620 can be highly transmissive and highly scattering. This means, that according to the embodiments discussed above, the light can be scattered only by the first layer, only by the second layer, only by the encapsulating material, or by any combination of the first layer, the second layer, and the encapsulating material.

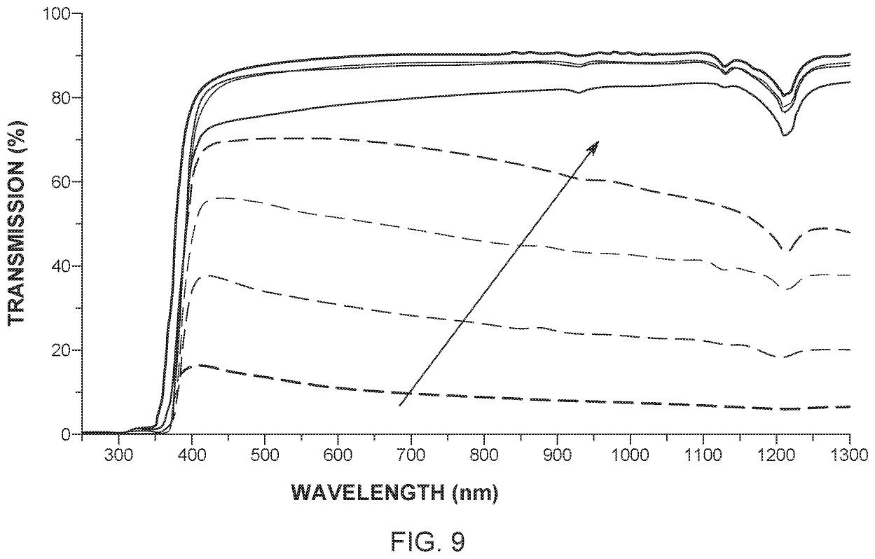

In this respect, FIG. 9 shows the light transmission in percentage measured for test samples of different combinations of front and back sheets (without integrated opaque solar cells 100). The solid lines depict the light transmission of the samples in percent (accounting for transmission and scattering) versus the wavelength of the light, while the dashed lines represent the fraction of transmitted light that is scattered upon passing all elements of the modules 600, 700 or 800, i.e., scattered transmitted light, as opposed to light that is transmitted without being scattered. The results show that through engineering of the optical properties (extinction, transmission, scattering) of the front and back sheets 610 and 620 and/or the encapsulating material 630, it is possible to control the overall optical effect of the combination of the elements of the solar module. For example, the arrow in the figure indicates that an increasing scattering can be obtained by just selecting different materials for the sheets.

In one configuration that was used for measuring the data illustrated in FIG. 9, a highly transparent (diffuse light transmission of less than 5%) plastic foil was used as the front sheet, but this could also be a regular high transparent glass (typically, diffuse light transmission of less than 3% and total light transmission of 90%) pane. Alternatively, a highly transparent and scattering plastic film or glass pane (diffuse light transmission of more than 50%) can be used as the front sheet. Another plastic selected for its good transparency and scattering properties was used as the back sheet. Again, the back sheet could be replaced by a glass pane with high transparency and scattering properties.

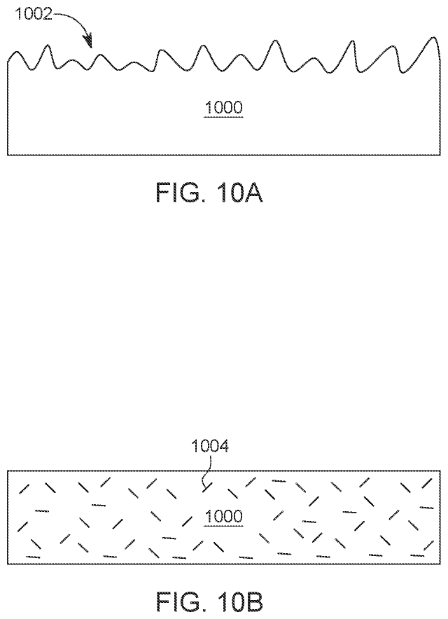

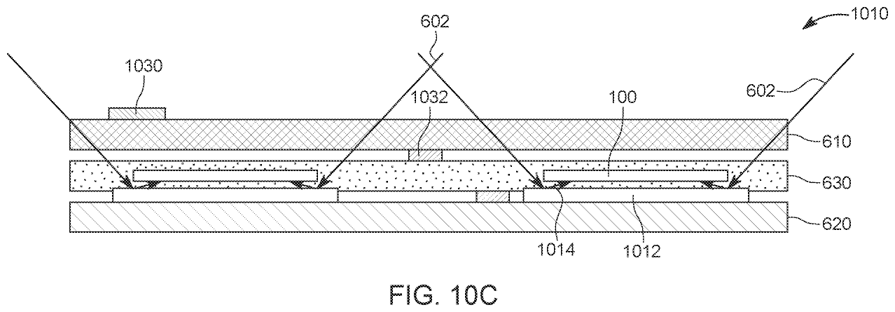

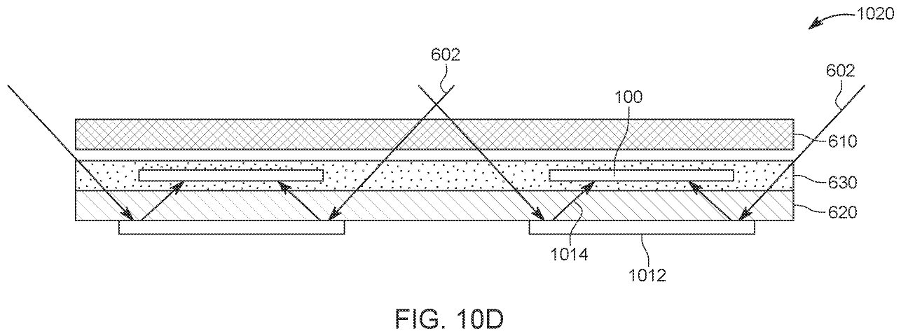

As discussed above, any of the front and back laminating sheets and/or the encapsulant material may incorporate light scattering features. These light scattering elements can be achieved by structuring the surface of the respective sheet or material at the nanometer scale, e.g., surface roughening. In one application, as illustrated in FIG. 10A, surface roughening 1002 of a given material 1000 can be accomplished using surface treatments commonly referred to as etching, texturing, or plasma treatment. Alternatively, light scattering features such as nanoelements 1004, e.g., nanoparticles, nanofibers, nanotubes, nanowires with dimensions in the range of the wavelength of the visible light, can be embedded into the final material 1000, for example, a liquid polymer solution before forming the plastic through extrusion or other film forming processes. Other materials that change the light transparency upon a stimulus, like photochromic or electrochromic materials, that can also be embedded in the same way into the laminating material.

A highly reflective (e.g., white) sheet 1012 may be added between the encapsulant material 630 and the back sheet 620, as shown in the implementation 1010 of FIG. 10C, or behind the back sheet 620, as shown in the implementation 1020 of FIG. 10D. The highly reflective sheet 1012 may be engineered to waveguide the light 602, which hits between the cells 100, back to the cells 100, as schematically illustrated in FIGS. 10C and 10D. The waveguided light 1014 will increase the current generated by the solar cells 100. The effect of the highly reflective white sheet 1012 on the generated current is relevant when using bifacial solar cells. This highly reflective white sheet 1012 could be added in strips or as a continuous sheet and as an opaque or a partially transmissive layer to properly control the light transmission and the light uniformity to the viewer behind the solar module. The reflector layer 1012 is either uniformly applied or striped to minimize the shading pattern cast below the modules while increasing the solar cell generated current.

Any of the above embodiments may be combined with one or more of the following features (illustrated in FIG. 10C) for achieving superior light management and power conversion efficiency: A) the first sheet is coated with an anti-reflection coating 1030 to minimize the reflection of the incident light and maximize the light capturing for increasing the solar cell generated current, and B) a layer 1032 for matching the refractive index is embedded between the first sheet and the encapsulant with the aim of trapping the light in the module for increasing the solar cell generated current. Note that these features do not have to be combined with the other features in FIG. 10C. These features can be used in any of the above discussed implementations.

The opaque solar cells 100 described above may be any solar cell based on a wafer, e.g., crystalline silicon or multi-crystalline or amorphous silicon solar cells, and also any solar cell that is deposited on a given substrate and it is opaque, and these solar cells are connected into strings using narrow Cu strips that provide the electrical connection from one cell to the next. The spacing between the cells 100 is used to control the reduction of the light intensity (shading level) provided by the module 400.

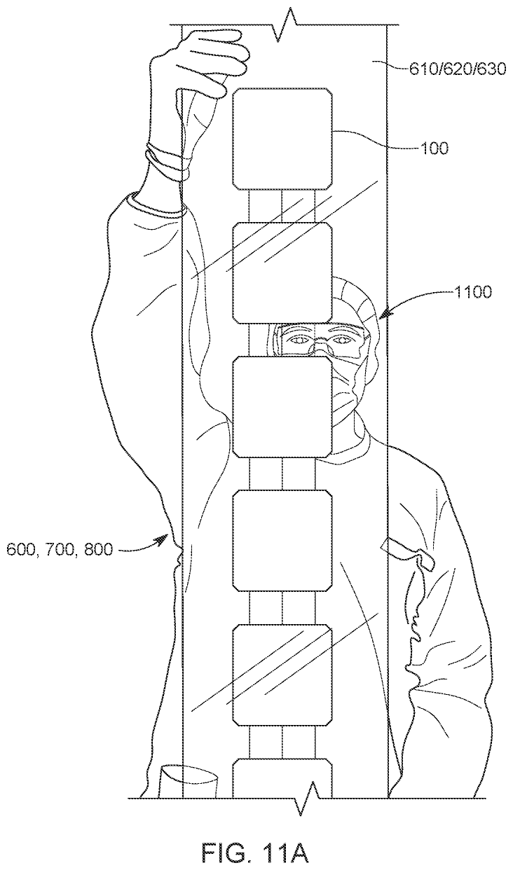

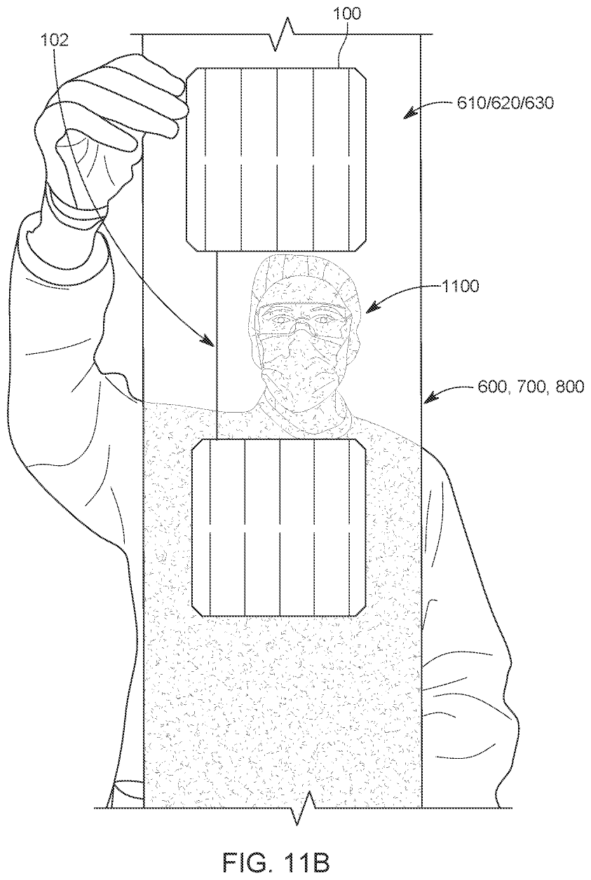

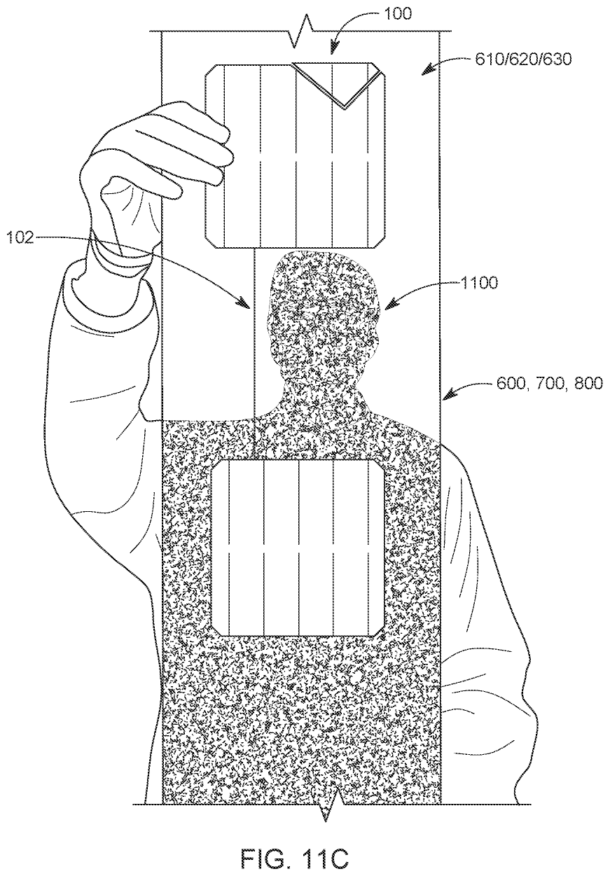

The components of the solar module 400 can be combined into a single unit by vacuum lamination using an encapsulant (such as EVA, POE or PVB) that embeds the cells 100 and provides the mechanical adhesion between the different components 610, 620, and 630. In this regard, FIGS. 11A to 11C show different optical light effects (levels of scattering) for different combinations of front and back sheets, with FIG. 11A showing high transmittance and low scattering front and back sheets (note that the face 1100 of the person holding the module 600/700/800 is clearly visible), FIG. 11B showing one of the first and second sheets having a high scattering feature (note that the face 1100 of the person holding the module 600/700/800 is not very clear), and FIG. 11C showing both the first and second sheets having a high scattering feature (note that the face 1100 of the person holding the module 600/700/800 is barely visible). Also note that the various solar cells 100 can be interconnected with corresponding wires 102 to form the solar module 600/700/800 that might have a single input and a single output.

In one application, the module 600//700/800 has a weight smaller than 2 kg/m² and a total light transmission between 10 and 70% and a light scattering (diffusion) between 10 and 60% due to the light materials used by the first and second sheets and the encapsulating material.

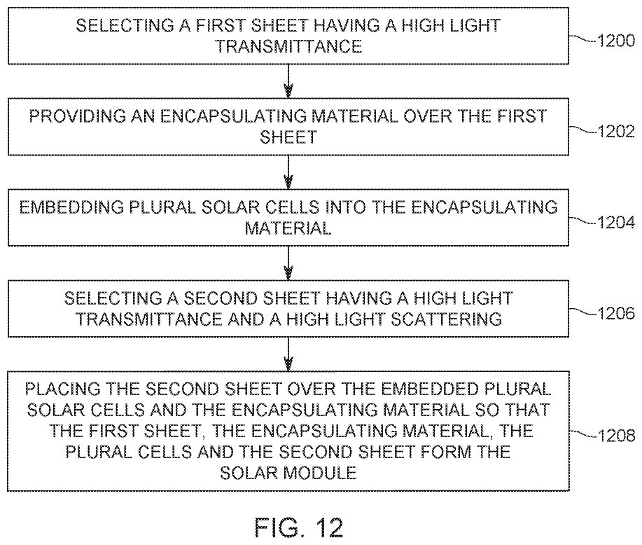

A method for generating substantially uniform light intensity behind a solar module 600 includes a step 1200 of selecting a first sheet 610 having a high light transmittance, a step 1202 of providing an encapsulating material 630 over the first sheet 610, a step 1204 of embedding plural solar cells 100 into the encapsulating material 630, a step of selecting 1206 a second sheet 620 having a high light transmittance and a high light scattering, and a step 1208 of placing the second sheet 620 over the embedded plural solar cells 100 and the encapsulating material 630 so that the first sheet, the encapsulating material, the plural cells and the second sheet form the solar module 600, shown in FIG. 12. The incident light on the first sheet scatters after passing the second sheet so that the passing light does not produce minima and maxima of light intensities. In one application, at least one of the first sheet and the encapsulating material has the high light transmittance and the high light scattering.

The disclosed embodiments provide a photovoltaic module that allows part of the light to pass through it and also manipulates the direction of the light so that almost uniform light intensity distribution is obtained after the light has passed through the module. It should be understood that this description is not intended to limit the invention. On the contrary, the embodiments are intended to cover alternatives, modifications and equivalents, which are included in the spirit and scope of the invention as defined by the appended claims. Further, in the detailed description of the embodiments, numerous specific details are set forth in order to provide a comprehensive understanding of the claimed invention. However, one skilled in the art would understand that various embodiments may be practiced without such specific details.

Although the features and elements of the present embodiments are described in the embodiments in particular combinations, each feature or element can be used alone without the other features and elements of the embodiments or in various combinations with or without other features and elements disclosed herein.

This written description uses examples of the subject matter disclosed to enable any person skilled in the art to practice the same, including making and using any devices or systems and performing any incorporated methods. The patentable scope of the subject matter is defined by the claims, and may include other examples that occur to those skilled in the art. Such other examples are intended to be within the scope of the claims.

1. A photovoltaic module for transforming an incident light into electrical energy, the photovoltaic module comprising:
plural solar cell configured to transform the incident light into the electrical energy;
a first sheet that is transparent to the incident light; and
a second sheet that is transparent to the incident light,
wherein the plural solar cells are sandwiched between the first sheet and the second sheet, and
wherein at least one of the first and second sheets has a high transparency regarding the incident light and also a high scattering of the incident light.

2. The module of claim 1, wherein the high transparency is defined as allowing more than 85% light transmission of the incident light.

3. The module of claim 2, wherein the high scattering feature is defined as scattering more than 40% of a transmitted light.

4. The module of claim 1, wherein both the first and second sheets have the high transparency and the high scattering.

5. The module of claim 1, wherein the plural solar cells are opaque to the incident light.

6. The module of claim 5, wherein the plural solar cells are made of silicon.

7. The module of claim 1, further comprising:
an encapsulating material distributed between the first and second sheets to hold the first and second sheets together.

8. The module of claim 7, wherein the encapsulating material fully encapsulates the plural solar cells.

9. The module of claim 8, wherein the encapsulating material fully extends between the first and second sheets so that the first sheet does not directly touches the second sheet.

10. The module of claim 7, wherein the encapsulating material has the high transparency regarding the incident light and also the high scattering of the incident light.

11. The module of claim 7, wherein each of the first sheet, the second sheet, and the encapsulating material has the high transparency regarding the incident light and also the high scattering of the incident light.

12. The module of claim 1, wherein light passing through the module does not produce minima and maxima of light intensities.

13. A photovoltaic module for transforming an incident light into electrical energy, the photovoltaic module comprising:
plural solar cells configured to transform the incident light into the electrical energy;
a first sheet that is transparent to the incident light;
a second sheet that is transparent to the incident light; and
an encapsulating material distributed between the first and second sheets to hold the first and second sheets together,
wherein the plural solar cells and the encapsulating material are sandwiched between the first sheet and the second sheet, and
wherein at least one of the first and second sheets has a high transparency regarding the incident light and also a high scattering of the incident light.

14. The module of claim 13, wherein the high transparency is defined as allowing more than 85% light transmission of the incident light.

15. The module of claim 14, wherein the high scattering feature is defined as scattering more than 40% of a transmitted light.

16. The module of claim 13, wherein both the first and second sheets have the high transparency and the high scattering.

17. The module of claim 13, where in the encapsulating material has the high transparency regarding the incident light and also the high scattering of the incident light.

18. The module of claim 13, wherein each of the first sheet, the second sheet, and the encapsulating material has the high transparency regarding the incident light and also the high scattering of the incident light.

19. A method for generating substantially uniform light intensity behind a solar module, the method comprising:
selecting a first sheet having a high light transmittance;
providing an encapsulating material over the first sheet;
embedding plural solar cells into the encapsulating material;
selecting a second sheet having a high light transmittance and a high light scattering; and
placing the second sheet over the embedded plural solar cells and the encapsulating material so that the first sheet, the encapsulating material, the plural cells and the second sheet form the solar module,
wherein incident light on the first sheet scatters after passing the second sheet so that the passing light does not produce minima and maxima of light intensities.

20. The method of claim 19, wherein at least one of the first sheet and the encapsulating material has the high light transmittance and the high light scattering.
